(19) United States
(12) Patent Application Publication
(10) Pub. No.: US 2024/0332109 A1
(43) Pub. Date: Oct. 3, 2024

(54) SEMICONDUCTOR DEVICE

(71) Applicant: SHINKO ELECTRIC INDUSTRIES CO., LTD., Nagano-shi (JP)

(72) Inventor: Shinichiro Sekijima, Nagano (JP)

(21) Appl. No.: 18/612,214

(22) Filed: Mar. 21, 2024

(30) Foreign Application Priority Data
Mar. 29, 2023 (JP) 2023-052552

(51) Int. Cl. H01L 23/31; H01L 23/00

(52) U.S. Cl. CPC H01L 23/3185; H01L 24/16; H01L 2224/16227; H01L 2924/18161; H01L 2924/3512

(57) ABSTRACT

A semiconductor device includes a wiring substrate, a semiconductor chip, and a sealing resin. The semiconductor chip is mounted on the wiring substrate. The sealing resin is filled in a gap between the wiring substrate and the semiconductor chip and extends to an upper surface of the semiconductor chip. The semiconductor chip includes a groove that is formed in an outer peripheral area that is located around a circumference of a predetermined area disposed on the upper surface of the semiconductor chip and that includes a peripheral edge of the upper surface of the semiconductor chip, and that captures an extending portion of the sealing resin extends.

### CROSS-REFERENCE TO RELATED APPLICATION

This application is based upon and claims the benefit of priority of the prior Japanese Patent Application No. 2023-052552, filed on Mar. 29, 2023, the entire contents of which are incorporated herein by reference.

### FIELD

The embodiment discussed herein is related to a semiconductor device.

### BACKGROUND

A semiconductor device is manufactured by mounting a semiconductor chip on, for example, a wiring substrate. Furthermore, a sealing resin that is referred to as an underfill resin is filled in a gap between the wiring substrate and a semiconductor chip, an electrical connection portion between the wiring substrate and the semiconductor chip is protected.

This type of the sealing resin is filled in a gap between the wiring substrate and the semiconductor chip by using, for example, a nozzle that discharges the sealing resin (hereinafter, referred to as a “resin discharge nozzle”). At this time, the sealing resin laterally flows out from the gap between the wiring substrate and the semiconductor chip, and may possibly soil other parts, a pad, or the like arranged around a circumference of, for example, the semiconductor chip.

In contrast, in order to avoid a lateral flow of the sealing resin, there is a proposed technology for supplying a sealing resin from a resin discharge nozzle to a peripheral edge of an upper surface of a semiconductor chip, filling the sealing resin into a gap between a wiring substrate and a semiconductor chip, and allowing the sealing resin to extend to an upper surface of the semiconductor chip.

Patent Document 1: Japanese Laid-open Patent Publication No. 11-345834

However, with the technology described above, there is a problem in that the sealing resin flows into a predetermined area that is disposed on the upper surface of the semiconductor chip, and the height of the sealing resin is increased. In other words, for example, there may be a case in which a print area that is used for printing is provided at the central part of the upper surface of the semiconductor chip. In such a case, if the sealing resin extends to the upper surface of the semiconductor chip, an extended portion flows into the print area, and thus, the use of the print area may possibly be inhibited. Furthermore, it is conceivable that the entire height of the sealing resin is increased by an amount corresponding to the thickness of the extended portion of the sealing resin that extends to the upper surface of the semiconductor chip. If the height of the sealing resin is increased, for example, in the case where an external component is arranged at an upper part of the semiconductor chip, a problem that a crack occurs in the sealing resin caused by an interference between the sealing resin and the external component.

### SUMMARY

According to an aspect of an embodiment, a semiconductor device includes a wiring substrate; a semiconductor chip that is mounted on the wiring substrate; and a sealing resin that is filled in a gap between the wiring substrate and the semiconductor chip and that extends to an upper surface of the semiconductor chip, wherein the semiconductor chip includes a groove that is formed in an outer peripheral area located around a circumference of a predetermined area disposed on the upper surface of the semiconductor chip, the outer peripheral area including a peripheral edge of the upper surface of the semiconductor chip, and that captures an extending portion of the sealing resin.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating a configuration of a semiconductor device according to an embodiment;

FIG. 2 is a plan view of the semiconductor device according to the embodiment when viewed from an upward direction;

FIG. 3 is a diagram illustrating a specific example of a resin filling step;

FIG. 4 is a cross-sectional view illustrating a configuration of a semiconductor device according to a first modification of the embodiment;

FIG. 5 is a plan view of a semiconductor device according to the first modification of the embodiment when viewed from an upward direction;

FIG. 6 is a cross-sectional view illustrating a configuration of a semiconductor device according to a second modification of the embodiment;

FIG. 7 is a plan view of the semiconductor device according to the second modification of the embodiment when viewed from an upward direction;

FIG. 8 is a cross-sectional view illustrating a configuration of a semiconductor device according to a third modification of the embodiment; and

FIG. 9 is a cross-sectional view illustrating a configuration of a semiconductor device according to a fourth modification of the embodiment.

### DESCRIPTION OF EMBODIMENTS

Preferred embodiments of a semiconductor device disclosed in the present invention will be described in detail below with reference to the accompanying drawings. Furthermore, the disclosed technology is not limited by the embodiments.

### Embodiment

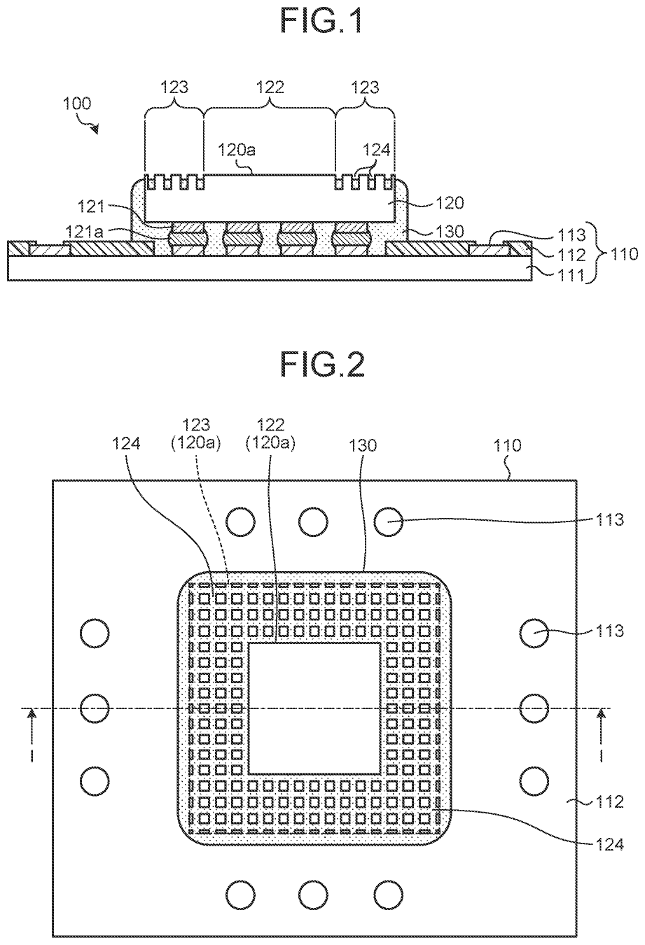

FIG. 1 is a cross-sectional view illustrating a configuration of a semiconductor device 100 according to an embodiment. The semiconductor device 100 is constituted such that a semiconductor chip 120 is mounted on a wiring substrate 110. Then, a sealing resin 130 that is referred to as an underfill resin is filled in a gap between the wiring substrate 110 and the semiconductor chip 120, and the sealing resin 130 extends to an upper surface 120a of the semiconductor chip 120 after extending around the side surface of the semiconductor chip 120. In the following, for the sake of convenience, a description will be made on the assumption that the direction from the wiring substrate 110 toward the semiconductor chip 120 is an upward direction, and the direction from the semiconductor chip 120 toward the wiring substrate 110 is a downward direction; however, the semiconductor device 100 may be manufactured or used in an arbitrary orientation by, for example, vertically inverting the surfaces of the semiconductor device 100.

The wiring substrate 110 includes a substrate 111, a solder resist layer 112, and upper surface pads 113. Furthermore, although not illustrated in FIG. 1, each of the upper surface pads 113 may electrically be connected to a lower surface pad (not illustrated) that is disposed on the lower portion of the substrate 111 by via wiring that passes through the substrate 111.

The substrate 111 is a plate-shaped member having an insulation property, and is a base material of the wiring substrate 110. A material of the substrate 111 used may be a glass epoxy resin, or the like that is formed by impregnating, for example, glass cloth (a glass woven fabric) that is a reinforcement material with a thermosetting insulation-property resin made of an epoxy resin as a main component and being cured. The reinforcement material used may, in addition to the glass cloth, for example, a glass non-woven fabric, an aramid woven fabric, an aramid non-woven fabric, a liquid crystal polymer (LCP) woven fabric, a LCP non-woven fabric, or the like. Furthermore, the thermosetting insulation-property resin used may be, in addition to the epoxy resin, for example, a polyimide resin, a cyanate resin, or the like.

Furthermore, the substrate 111 is not limited to an insulation property member having a single layer, but may be a laminated substrate having a multi layered structure constituted by laminating an insulating layer and a wiring layer. In the case where the substrate 111 is the laminated substrate, the wiring layer that sandwiches the insulating layer is electrically connected by a via that passes through the insulating layer. The material of the insulating layer used may be, for example, an insulation-property resin, such as an epoxy resin or a polyimide resin, or a resin material made by mixing the epoxy resin or the polyimide resin in a filler made of silica, alumina, or the like. Furthermore, the material of the wiring layer used may be, for example, copper (Cu) or a copper alloy.

The solder resist layer 112 is an insulating layer that covers the upper surface of the substrate 111. An opening portion is provided on a part of the solder resist layer 112, and each of the upper surface pads 113 is exposed from the opening portion. The material of the solder resist layer 112 used may be, for example, an insulation-property resin, such as an epoxy-based resin or an acrylic-based resin.

Each of the upper surface pads 113 is formed on the wiring layer disposed on the upper surface of the substrate 111, and is exposed from the opening portion of the solder resist layer 112 in order for packaging of the semiconductor chip 120 and packaging of an external component (not illustrated). In other words, the semiconductor chip 120 is connected to some of the upper surface pads 113 as a flip chip interconnect. Furthermore, some of the other of the upper surface pads 113 to which the semiconductor chip 120 is not connected are arranged around the circumference of the upper surface pads 113 that are connected to the semiconductor chip 120, are partly exposed from the opening portion of the solder resist layer 112, and are used as external connection terminals with respect to the external components. When the semiconductor chip 120 is mounted on the upper surface of the wiring substrate 110, terminals 121 that are formed on the lower surface of the semiconductor chip 120 are connected to the upper surface pads 113 by respective pieces of solder 121a. Then, the sealing resin 130 is filled in a gap between the wiring substrate 110 and the semiconductor chip 120, and the connection portion between each of the terminals 121 and the respective upper surface pads 113 is protected. The material of the upper surface pads 113 used may be, similarly to the wiring layer, for example, copper or a copper alloy.

The semiconductor chip 120 is an electronic component in which electronic circuits having various functions are integrated on a semiconductor. The plurality of terminals 121 are provided on the lower surface located opposite the wiring substrate 110 of the semiconductor chip 120, and are connected to the respective upper surface pads 113 included in the wiring substrate 110, as described above.

The sealing resin 130 is filled in the gap between the wiring substrate 110 and the semiconductor chip 120, and extends from the side surface of the semiconductor chip 120 to the upper surface 120a of the semiconductor chip 120. The material of the sealing resin 130 used may be, for example, an insulation-property resin, such as an epoxy-based resin.

FIG. 2 is a plan view of the semiconductor device 100 according to the embodiment when viewed from the upward direction. In FIG. 2, the upper surface 120a of the semiconductor chip 120 having a rectangular shape is illustrated. The cross sectional surface taken along line I-I illustrated in FIG. 2 corresponds to the cross-sectional view illustrated in FIG. 1. As illustrated in FIG. 1 and FIG. 2, the upper surface 120a of the semiconductor chip 120 on which the sealing resin 130 extends includes a print area (one example of a predetermined area) 122 and an outer peripheral area 123.

The print area 122 is an area for printing various kinds of information including, for example, a product number, and the like of the semiconductor chip 120. The print area 122 is provided at the central part of the upper surface 120a of the semiconductor chip 120. It is desirable that the print area 122 is not covered by the sealing resin 130 in order to maintain visibility of the printing.

The outer peripheral area 123 is an area that is located around the circumference of the print area 122 and that includes a peripheral edge of the upper surface 120aof the semiconductor chip 120. Grooves 124 are formed in the outer peripheral area 123. Each of the grooves 124 captures a portion of the sealing resin 130 extending to the upper surface 120a of the semiconductor chip 120. Specifically, each of the grooves 124 has a width and a depth that are minute enough to occur capillary action with respect to the sealing resin 130, and captures the portion of the sealing resin 130 extending to the upper surface 120a of the semiconductor chip 120, by the capillary action. The width of each of the grooves 124 may be set to, for example, about 50 to 1000 μm, and the depth of each of the grooves 124 may be set to, for example, about 1 to 100 μm. The grooves 124 are able to be formed by, for example, laser beam machining.

In this way, in the embodiment, the extending portion of the sealing resin 130 is captured by forming the grooves 124 in the outer peripheral area 123 that is located around the circumference of the print area 122 that is located on the upper surface 120a of the semiconductor chip 120. Accordingly, the portion to which the sealing resin 130 extends is stored in the groove 124, and the upper surface of the portion to which the sealing resin 130 extends is located at a position lower than the height of the upper surface 120a of the semiconductor chip 120. Accordingly, in the outer peripheral area 123, a flow of the sealing resin 130 is limited by the capillary action of the groove 124, and the sealing resin 130 spreads thinly in the longitudinal direction of the groove 124. As a result of this, according to the embodiment, it is possible to avoid an inflow of the sealing resin 130 into the print area 122 that is located on the upper surface 120a of the semiconductor chip 120, and it is also possible to suppress an increase in the height of the sealing resin 130.

As illustrated in FIG. 2, each of the grooves 124 is formed at a location along the four sides that constitute the peripheral edge of the upper surface 120a of the semiconductor chip 120 located in the outer peripheral area 123 on the upper surface 120a of the semiconductor chip 120. As a result of this, even when the sealing resin 130 is supplied to the peripheral edge of the upper surface 120a of the semiconductor chip 120 by using a resin discharge nozzle, it is possible to limit the flow of the sealing resin 130 in the vicinity of the four sides that constitute the peripheral edge of the upper surface 120a. Accordingly, it is possible more stably avoid the inflow of the sealing resin 130 into the print area 122.

Furthermore, in FIG. 2, a case has been described as an example in which the grooves 124 constitute the peripheral edge of the upper surface 120a of the semiconductor chip 120; however, the disclosed technology is not limited to this. For example, the grooves 124 may be formed on at least a side that constitutes the peripheral edge of the upper surface 120a in the outer peripheral area 123 that is located on the upper surface 120a of the semiconductor chip 120. In this case, the grooves 124 may be formed on one or more side that is located on the side closer to the resin discharge nozzle from among the four sides that constitute the peripheral edge of the upper surface 120a.

The plurality of grooves 124 are formed in the outer peripheral area 123. Furthermore, the plurality of grooves 124 are arranged in a grid-shaped manner. In other words, the plurality of grooves 124 that extend in a linear manner in different directions in a plan view are arranged so as to be intersecting each other. As a result of the plurality of grooves 124 being formed in the outer peripheral area 123, it is possible to efficiently limit the flow of the sealing resin 130 by the capillary action of the plurality of grooves 124 in the outer peripheral area 123, and it is also possible to more thinly spread the sealing resin 130. Consequently, according to the embodiment, it is possible to more stably avoid the flow of the sealing resin 130 into the print area 122 that is located on the upper surface 120a of the semiconductor chip 120, and it is also possible to suppress an increase in the height of the sealing resin 130.

Furthermore, the arrangement of the plurality of grooves 124 in the outer peripheral area 123 is not limited to the grid shape illustrated in FIG. 2. For example, the plurality of concentric grooves 124 that are continuously depressed in a rectangular shape in a plan view may be arranged around the print area 122.

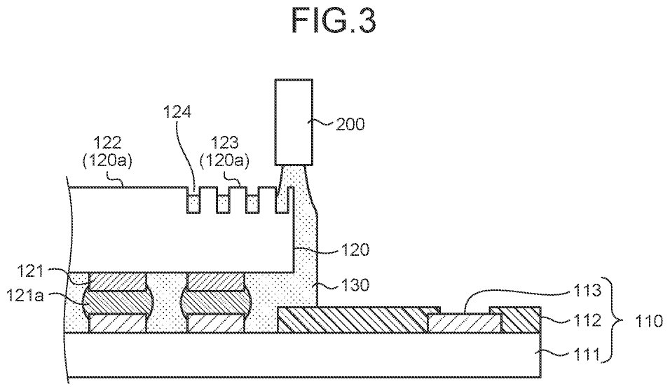

In the following, a sealing resin filling step that is performed when the semiconductor device 100 having the above described configuration is manufactured will be explained with reference to FIG. 3. FIG. 3 is a diagram illustrating a specific example of the sealing resin filling step. In FIG. 3, a state in which the semiconductor chip 120 is mounted on the upper surface of the wiring substrate 110 is illustrated.

When the semiconductor chip 120 is mounted on the upper surface of the wiring substrate 110, first, a resin discharge nozzle 200 is arranged on an upper portion of the peripheral edge of the upper surface 120a of the semiconductor chip 120.

Then, the sealing resin 130 that is an uncured state is supplied from the resin discharge nozzle 200 to the peripheral edge of the upper surface 120a of the semiconductor chip 120. The sealing resin 130 that is supplied from the resin discharge nozzle 200 is filled in the gap between the wiring substrate 110 and the semiconductor chip 120 by way of the side surface of the semiconductor chip 120, and extends to the upper surface 120a of the semiconductor chip 120 after extending around the side surface of the semiconductor chip 120.

Here, in the outer peripheral area 123 that is located at the circumference of the print area 122 that is located on the upper surface 120a of the semiconductor chip 120, each of the grooves 124 that captures the extending portion of the sealing resin 130 is formed. Accordingly, the portion in which the sealing resin 130 extends is stored in each of the grooves 124, and the upper surface of the portion in which the sealing resin 130 extends is located at the position lower than the height of the upper surface 120a of the semiconductor chip 120. As a result of this, the flow of the sealing resin 130 is limited in the outer peripheral area 123 due to the capillary action of each of the grooves 124, and the sealing resin 130 thinly spreads in the longitudinal direction of the groove 124. Consequently, an inflow of the sealing resin 130 into the print area 122 that is located on the upper surface 120a of the semiconductor chip 120 is avoided and an increase in the height of the sealing resin 130 is also suppressed. Accordingly, the print area 122 is prevented from being covered by the sealing resin 130, the use of the print area 122 is prevented from being inhibited. Furthermore, even in the case where the external component is arranged at an upper portion of the semiconductor chip 120 by using the upper surface pad 113 included in the wiring substrate 110, it is possible to avoid an interference between the sealing resin 130 and the external component, and it is thus possible to prevent a crack occurring in the sealing resin 130.

When the sealing resin 130 that is the uncured state is filled in the gap between the wiring substrate 110 and the semiconductor chip 120 and extends to the upper surface 120a of the semiconductor chip 120, the sealing resin 130 is heated by a predetermined temperature and is cured.

### Modification

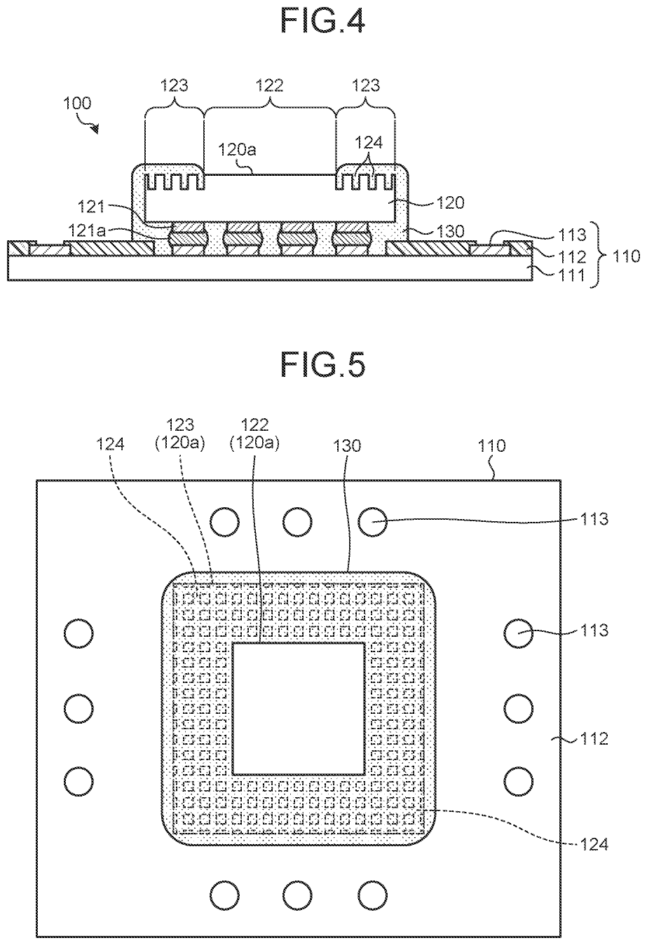

In the following, various modifications of the semiconductor device 100 according to the embodiment will be described with reference to FIG. 4 to FIG. 9. FIG. 4 is a cross-sectional view illustrating a configuration of the semiconductor device 100 according to a first modification of the embodiment. FIG. 5 is a plan view of the semiconductor device 100 according to the first modification of the embodiment when viewed from an upward direction.

Furthermore, in the various modifications that will be described below, by assigning the same reference numerals to the same components as those described in the embodiment, overlapping descriptions thereof will be sometimes omitted.

As illustrated in FIG. 4 and FIG. 5, in the semiconductor device 100 according to the first modification, a configuration of the sealing resin 130 is different from that described in the embodiment. Specifically, in a portion in which the sealing resin 130 extends to the upper surface 120a of the semiconductor chip 120, the sealing resin 130 upheaves to a position that is higher than that of the upper surface 120a of the semiconductor chip 120 and covers the outer peripheral area 123 that is located in the upper surface 120a of the semiconductor chip 120. In other words, in the first modification, the portion to which the sealing resin 130 extends is stored in the grooves 124, and the upper surface of the portion to which the sealing resin 130 extends upheaves to a position that is higher than that of the height of the upper surface 120a of the semiconductor chip 120 and covers the entire of the outer peripheral area 123.

As a result of this, the semiconductor chip 120 is sandwiched by the sealing resin 130 from both sides of the upper surface 120a and the lower surface of the semiconductor chip 120, so that it is possible to stably secure the semiconductor chip 120. Therefore, according to the first modification, it is possible to prevent the semiconductor chip 120 from peeling off from the sealing resin 130 and occurrence of a warp in the semiconductor chip 120 caused by a difference in a coefficient of thermal expansion between the semiconductor chip 120 and the sealing resin 130.

Furthermore, the sealing resin 130 according to the first modification upheaves to a position that is higher than that of the upper surface 120a of the semiconductor chip 120. As a result of this, the sealing resin 130 is uniformly leveled by the capillary action produced by each of the grooves 124, so that it is possible to suppress an interference generated when the external component is arranged at the upper portion of the semiconductor chip 120 to the minimum as compared with a case in which a part of the sealing resin 130 protrudes and upheaves.

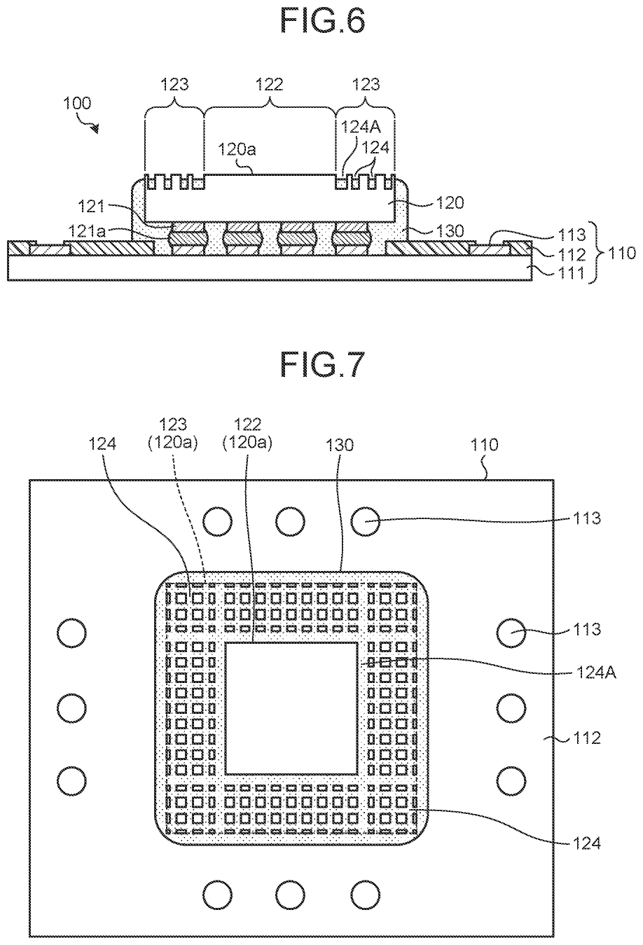

FIG. 6 is a cross-sectional view illustrating a configuration of the semiconductor device 100 according to a second modification of the embodiment. FIG. 7 is a plan view of the semiconductor device 100 according to the second modification of the embodiment viewed from the upward direction.

As illustrated in FIG. 6 and FIG. 7, in the semiconductor device 100 according to the second modification, a configuration of the plurality of grooves 124 is different from that described in embodiment. Specifically, from among the plurality of grooves 124, a groove 124A that is arranged at the position closest to the print area 122 has a width that is larger than that of the other grooves 124 except for the groove 124A that is located at the position closest to the print area 122.

As a result of this, a volume of the groove 124A located at the position closest to the print area 122 is increased, so that it is possible to retain the flow of the sealing resin 130 toward the print area 122 in the groove 124A even when an amount of supply of the sealing resin 130 received from the resin discharge nozzle 200 is relatively large. Therefore, according to the second modification, it is possible to stably avoid the flow of the sealing resin 130 into the print area 122 that is located on the upper surface 120a of the semiconductor chip 120.

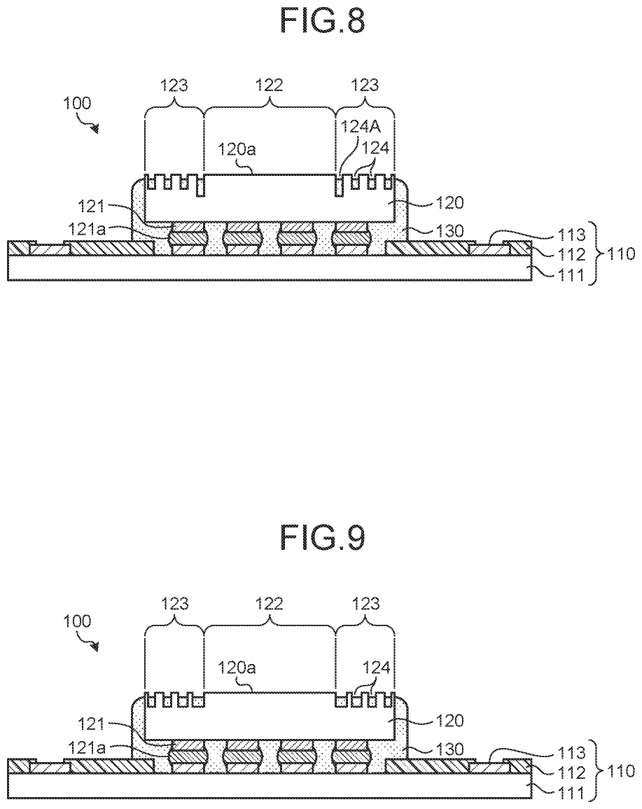

FIG. 8 is a cross-sectional view illustrating a configuration of the semiconductor device 100 according to a third modification of the embodiment.

As illustrated in FIG. 8, in the semiconductor device 100 according to the third modification, the configuration of the plurality of grooves 124 is different from that described in the embodiment. Specifically, from among the plurality of grooves 124, the groove 124A that is arranged at the position closest to the print area 122 has a depth that is deeper than the other grooves 124 except for the groove 124A that is located at the position closest to the print area 122.

As a result of this, the volume of the groove 124A that is located closest to the print area 122 is increased, so that it is possible to retain the flow of the sealing resin 130 toward the print area 122 in the groove 124A even when an amount of supply of the sealing resin 130 received from the resin discharge nozzle 200 is relatively large. Therefore, according to the third modification, it is possible to stably avoid the flow of the sealing resin 130 into the print area 122 that is located on the upper surface 120a of the semiconductor chip 120.

Furthermore, in the third modification, the groove 124A that is located closest to the print area 122 may have a width that is larger than that of each of the other grooves 124 except for the groove 124A that is located at the position closest to the print area 122. In short, it is preferable that at least one of the width and the depth of the groove 124A that is located closest to the print area 122 is larger than the width or the depth of each of the other grooves 124 except for the groove 124A that is located at the position closest to the print area 122.

FIG. 9 is a cross-sectional view illustrating a configuration of the semiconductor device 100 according to a fourth modification of the embodiment.

As illustrated in FIG. 9, in the semiconductor device 100 according to the forth modification, the configuration of the plurality of grooves 124 is different from that described in embodiment. Specifically, the grooves 124 are constituted to have a larger width as the groove 124 is located closer to the print area 122 from among the plurality of grooves 124.

As a result of this, the volume of each of the grooves 124 is increased as the groove 124 is located closer to the print area 122 from among the plurality of grooves 124, so that it is possible to retain the flow of the sealing resin 130 toward the print area 122 in each of the grooves 124 even when an amount of supply of the sealing resin 130 received from the resin discharge nozzle 200 is relatively large. Therefore, according to the fourth modification, it is possible to stably avoid the flow of the sealing resin 130 into the print area 122 that is located on the upper surface 120a of the semiconductor chip 120.

Furthermore, in the fourth modification, the groove 124 that is located closer to the print area 122 from among the plurality of grooves 124 may have a larger depth. In short, the plurality of grooves 124 may be preferably constituted such that at least one of the width and the depth is larger as the groove 124 is located closer to the print area 122 from among the plurality of grooves 124.

As described above, as the semiconductor device (as one example, the semiconductor device 100) according to the embodiment includes the wiring substrate (as one example, the wiring substrate 110), the semiconductor chip (as one example, the semiconductor chip 120), and the sealing resin (as one example, the sealing resin 130). The semiconductor chip is mounted on the wiring substrate. The sealing resin is filled in the gap between the wiring substrate and the semiconductor chip and extends to the upper surface of the semiconductor chip. The semiconductor chip includes the groove (as one example, the groove 124) that is formed in the outer peripheral area (as one example, the outer peripheral area 123) located around the circumference of the predetermined area (as one example, the print area 122) disposed on the upper surface (as one example, the upper surface 120a) of the semiconductor chip, the outer peripheral area including the peripheral edge of the upper surface of the semiconductor chip, and that captures an extending portion of the sealing resin extends. As a result of this, it is possible to avoid a flow of the sealing resin into the predetermined area that is disposed on the upper surface of the semiconductor chip and also suppress an increase in the height of the sealing resin.

Furthermore, the groove may be formed at a position, included in the outer peripheral area that is located on the upper surface of the semiconductor chip, along at least a side that constitutes the peripheral edge of the upper surface of the semiconductor chip. As a result of this, it is possible to stably avoid the flow of the sealing resin into the predetermined area that is disposed on the upper surface of the semiconductor chip.

Furthermore, at a portion in which the sealing resin extends to the upper surface of the semiconductor chip, the sealing resin may upheave to a position that is higher than that of the upper surface of the semiconductor chip and may cover the outer peripheral area that is located on the upper surface of the semiconductor chip. As a result of this, it is possible to prevent the semiconductor chip from peeling off from the sealing resin and occurrence of a warp in the semiconductor chip caused by a difference in a coefficient of thermal expansion between the semiconductor chip and the sealing resin.

Furthermore, the semiconductor chip may have a plurality of grooves in the outer peripheral area. As a result of this, it is possible to stably avoid the flow of the sealing resin into the predetermined area that is located on the upper surface of the semiconductor chip, and it is also possible to suppress an increase in the height of the sealing resin.

Furthermore, the groove (as one example, the groove 124A) that is arranged at a position that is closest to the predetermined area from among the plurality of grooves may be constituted such that at least one of the width and the depth is larger than that of each of the other grooves except for the groove that is arranged at the position closest to the predetermined area. As a result of this, it is possible to stably avoid the flow of the sealing resin into the predetermined area that is disposed on the upper surface of the semiconductor chip.

Furthermore, the plurality of grooves may be constituted such that at least one of the width and the depth is larger as the groove is located closer to the predetermined area from among the plurality of grooves. As a result of this, it is possible to stably avoid the flow of the sealing resin into the predetermined area that is disposed on the upper surface of the semiconductor chip.

According to an aspect of an embodiment of the semiconductor device disclosed in the present application, an advantage is provided in that it is possible to avoid a flow of the sealing resin into the predetermined area that is disposed on the upper surface of the semiconductor chip and it is also possible to suppress an increase in the height of the sealing resin.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
a wiring substrate;
a semiconductor chip that is mounted on the wiring substrate; and
a sealing resin that is filled in a gap between the wiring substrate and the semiconductor chip and that extends to an upper surface of the semiconductor chip, wherein
the semiconductor chip includes a groove that is formed in an outer peripheral area located around a circumference of a predetermined area disposed on the upper surface of the semiconductor chip, the outer peripheral area including a peripheral edge of the upper surface of the semiconductor chip, and that captures an extending portion of the sealing resin.

2. The semiconductor device according to claim 1, wherein the groove is formed at a position, included in the outer peripheral area located on the upper surface of the semiconductor chip, along at least a side that constitutes the peripheral edge of the upper surface of the semiconductor chip.

3. The semiconductor device according to claim 1, wherein, at the extending portion that extends to the upper surface of the semiconductor chip, the sealing resin upheaves to a position that is higher than the upper surface of the semiconductor chip and covers the outer peripheral area located on the upper surface of the semiconductor chip.

4. The semiconductor device according to claim 1, wherein the semiconductor chip includes the plurality of grooves in the outer peripheral area.

5. The semiconductor device according to claim 4, wherein, the groove that is arranged at a position closest to the predetermined area from among the plurality of grooves is constituted such that at least one of a width and a depth is larger than that of each of another grooves except for the groove that is arranged at the position closest to the predetermined area.

6. The semiconductor device according to claim 4, wherein the plurality of grooves are constituted such that at least one of the width and the depth is larger as the groove is located closer to the predetermined area from among the plurality of grooves.

7. The semiconductor device according to claim 1, wherein an area in which the sealing resin is applied is located in the outer peripheral area of the semiconductor chip.
